(19) United States
(12) Patent Application Publication
(10) Pub. No.: US 2024/0420970 A1
(43) Pub. Date: Dec. 19, 2024

(54) LIQUID CIRCULATION SYSTEM, SUBSTRATE PROCESSING APPARATUS, AND LIQUID CIRCULATION METHOD

(71) Applicants: Tokyo Electron Limited, Tokyo (JP); Tokyo University of Science Foundation, Tokyo (JP)

(72) Inventors: Takao OKABE, Tokyo (JP); Hirokazu UEDA, Osaka (JP); Naoki UMESHITA, Tokyo (JP); Mitsuaki IWASHITA, Yamanashi (JP); Kenji SEKIGUCHI, Yamanashi (JP); Koji AKIYAMA, Yamanashi (JP); Tamotsu MORIMOTO, Yamanashi (JP); Toshikazu AKIMOTO, Tokyo (JP)

(21) Appl. No.: 18/703,525

(22) PCT Filed: Oct. 25, 2022
(86) PCT No.: PCT/JP2022/039719

§ 371 Date: Apr. 22, 2024

(30) Foreign Application Priority Data
Nov. 4, 2021 (JP) 2021-180011

(51) Int. Cl. H01L 21/67

(52) U.S. Cl. CPC H01L 21/67017

(57) ABSTRACT

A liquid circulation system according to an aspect of the present disclosure is for recovering an ionic liquid supplied into a vacuum chamber and returning the recovered ionic liquid back again into the vacuum chamber, and includes a storage tank having an opening communicating with an inside of the vacuum chamber and configured to store the ionic liquid recovered from the inside of the vacuum chamber through the opening, a viscosity pump provided below the storage tank in a vertical direction, and a pipe configured to supply the ionic liquid inside the storage tank into the vacuum chamber.

### TECHNICAL FIELD

The present disclosure relates to liquid circulation systems, substrate processing apparatuses, and liquid circulation methods.

### BACKGROUND ART

There is a known technique for supplying an ionic liquid into a vacuum chamber using a liquid pump (refer to Patent Document 1, for example).

### PRIOR ART DOCUMENTS

### Patent Document

Patent Document 1: Japanese Laid-Open Patent Publication No. 2014-239220

### DISCLOSURE OF THE INVENTION

### Problem to be Solved by the Invention

The present disclosure provides a technique capable of continuously circulating an ionic liquid in a vacuum.

### Means for Solving the Problem

According to one aspect of the present disclosure, a liquid circulation system for recovering an ionic liquid supplied into a vacuum chamber and returning the recovered ionic liquid back again into the vacuum chamber, includes a storage tank, having an opening communicating with an inside of the vacuum chamber, and configured to store the ionic liquid recovered from the inside of the vacuum chamber through the opening; a viscosity pump provided below the storage tank in a vertical direction; and a pipe configured to supply the ionic liquid inside the storage tank into the vacuum chamber.

### Effects of the Invention

According to the present disclosure, it is possible to continuously circulate an ionic liquid in a vacuum.

### BRIEF DESCRIPTION OF THE DRAWINGS

FIG. 1 is a diagram illustrating an example of a substrate processing apparatus according to an embodiment.

FIG. 2 is a perspective view in cross section illustrating an example of a liquid circulation system according to an embodiment.

FIG. 3 is a perspective view cross section illustrating a portion of a viscosity pump on an enlarged scale.

FIG. 4 is a diagram illustrating an example of a position of a joint provided in a pipe.

FIG. 5 is a cross sectional view illustrating an example of a connector between the viscosity pump and the pipe.

FIG. 6 is a cross sectional view illustrating another example of the connector between the viscosity pump and the pipe.

FIG. 7 is a diagram illustrating an example of an ionic liquid recycling mechanism.

FIG. 8 is a cross sectional view (1) illustrating an example of a high-temperature gate valve.

FIG. 9 is a cross sectional view (2) illustrating the example of the high-temperature gate valve.

FIG. 10 is a cross sectional view illustrating an example of a high-temperature compatible rotating seal.

### MODE OF CARRYING OUT THE INVENTION

Hereinafter, non-limiting embodiments for implementing the present disclosure will be described with reference to the drawings. In each of the drawings, the same or corresponding members or components are designated by the same or corresponding reference numerals, and a redundant description thereof will be omitted.

### [Circulation of Ionic Liquid in Ultra-High Vacuum Environment]

Demands for a mechanism enabling a nano-level motion in an ultra-high vacuum environment are increasing in the field of manufacturing semiconductors. Examples of a mechanical element enabling a smooth nano-level motion include a magnetic bearing and a fluid bearing. This is because the magnetic bearing and the fluid bearing undergo motion in a floating state, and there is no vibration or resistance caused by mechanical friction. The absence of vibration and resistance contributes to the ease of a nano-level positioning control and avoiding contamination caused by wear debris, and therefore, the magnetic bearing and the fluid bearing are suited for use in the field of manufacturing semiconductors requiring a processing accuracy at the nano-level under a clean environment. In particular, the fluid bearing is widely utilized in this field, because the fluid bearing has a higher bearing rigidity than the magnetic bearing and emits a smaller magnetic field than the magnetic bearing.

In recent years, there are demands to scale down semiconductor lithography according to large capacity of information. For this reason, a movement to use extreme ultra violet radiation (EUV) or electron beam (EB) as a lithography light source (beam source) is spreading. Because such low wavelength beams are absorbed and scattered by gas molecules, the lithography needs to be performed in an ultra-high vacuum environment. Hence, a processing target also needs to be positioned in the ultra-high vacuum environment.

However, there is a problem in that handling of the fluid bearing in a vacuum is difficult due to characteristics thereof using a gas or a liquid. A differential exhaust seal is an example of the fluid bearing for high vacuum. The differential exhaust seal is a mechanism that causes the bearing to float due to a gas under pressure, and thereafter sucks the gas using a vacuum pump before the gas is discharged in the ultra-high vacuum environment. The use of the differential exhaust seal enables a nano-level positioning accuracy to be obtained in the ultra-high vacuum environment. However, there is a problem in that the differential exhaust seal is a complex mechanism that is both expensive and bulky.

In addition, the magnetic bearing is an example of the fluid bearing for high vacuum. However, the magnetic bearing is likely to deteriorate the degree of vacuum, because a coil thereof generates heat and causes baking in the ultra-high vacuum environment. For this reason, the mechanism is placed in a low vacuum of 10⁻³ Pa, and only a beam irradiation part is sealed to a vacuum on the order of 10⁻⁵ Pa using the differential exhaust seal.

As a result of diligent studies, the present inventors conceived a liquid circulation system capable of continuously circulating an ionic liquid in a vacuum, and conceived a fluid bearing capable of simplifying a mechanism thereof and reducing the size and cost of the mechanism, by using the liquid circulation system. Details will be described below.

### [Substrate Processing Apparatus]

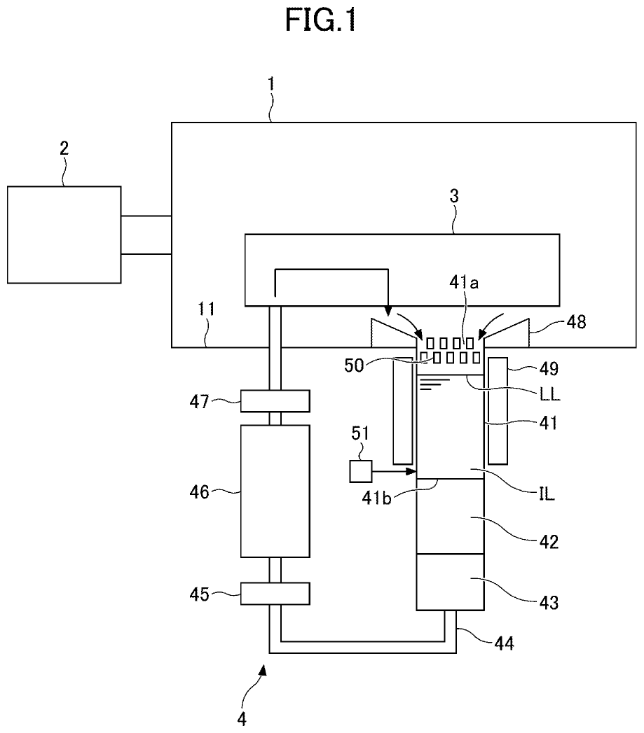

An example of a substrate processing apparatus according to an embodiment will be described with reference to FIG. 1. The substrate processing apparatus according to the embodiment performs various semiconductor processes with respect to a substrate, such as a semiconductor wafer, a glass substrate, or the like.

The substrate processing apparatus includes a processing chamber 1, an exhaust section 2, a liquid utilization section 3, and a liquid circulation system 4.

The processing chamber 1 is a vacuum chamber capable of maintaining an inside thereof at a predetermined degree of vacuum. The predetermined degree of vacuum is an ultra-high vacuum (10⁻⁸ Pa to 10⁻⁵ Pa) or a high vacuum (10⁻⁵ Pa to 10⁻¹ Pa), for example.

The exhaust section 2 exhausts the inside of the processing chamber 1 to depressurize the inside to the predetermined degree of vacuum. The exhaust section 2 includes a vacuum pump, an exhaust pipe, and a pressure control valve.

The liquid utilization section 3 is provided inside the processing chamber 1. The liquid utilization section 3 is a target that utilizes an ionic liquid supplied from the liquid circulation system 4. The liquid utilization section 3 is a vacuum seal, a temperature control target, or a static elimination target, for example.

Examples of the vacuum seal include a fluid bearing configured to seal a gate valve that opens and closes a loading and unloading port for loading the substrate into and unloading the substrate from the processing chamber 1, and a fluid bearing configured to seal a rotating shaft that rotates a rotary stage that rotatably holds the substrate inside the processing chamber I. Because the ionic liquid is nonvolatile in a vacuum under a high temperature, the ionic liquid can be supplied to the fluid bearing placed in a high-temperature vacuum. Hence, a vacuum seal can be achieved at high temperatures (for example, 240° C. or higher) at which the use of an O-ring is difficult.

A temperature control target may be a member (hereinafter, referred to as “a vacuum heat insulated member”) that is in vacuum insulation and provided inside the processing chamber 1. Examples of the vacuum heat insulated member include a motor and a substrate, for example. Because the ionic liquid is nonvolatile in the vacuum under the high temperature, the ionic liquid can be supplied to the vacuum heat insulated member placed in the vacuum. Accordingly, the vacuum heat insulated member can be cooled by supplying a low-temperature ionic liquid to the vacuum heat insulated member. In addition, the vacuum heat insulated member can be heated by supplying a high-temperature ionic liquid to the vacuum heat insulated member.

A static elimination target may be an electrically floating member (hereinafter, referred to as “a floating member”) provided inside the processing chamber 1, for example. Because the ionic liquid is nonvolatile in the vacuum, the ionic liquid can be supplied to the floating member placed in the vacuum. In addition, because the ionic liquid is conductive, the floating member can be eliminated of static via the ionic liquid, by supplying the ionic liquid to the floating member.

The liquid circulation system 4 is configured to circulate the ionic liquid by recovering the ionic liquid supplied to the liquid utilization section 3 inside the processing chamber 1 and returning the ionic liquid back again to the liquid utilization section 3. The liquid circulation system 4 will be described later in more detail.

### [Liquid Circulation System]

An example of the liquid circulation system according to an embodiment will be described with reference to FIG. 1 through FIG. 6.

The liquid circulation system 4 includes a storage tank 41, a viscosity pump 42, a diaphragm pump 43, a pipe 44, a discharge pressure sensor 45, a flow rate controller 46, a supply pressure sensor 47, a liquid recovery tray 48, a temperature controller 49, a splash shield 50, a measurement unit 51, and a frame 52.

The storage tank 41 stores an ionic liquid IL. The storage tank 41 has a cylindrical shape. An opening 41a at an upper end of the storage tank 41 communicates with the inside of the processing chamber 1. Thus, the ionic liquid IL is recovered from the processing chamber 1 into the storage tank 41 through the opening 41a, and a liquid level LL of the ionic liquid IL inside the storage tank 41 is exposed in a vacuum. In addition, because the ionic liquid IL is stored in the vacuum without being exposed to the atmosphere, it is possible to reduce characteristic deterioration of the ionic liquid IL, and as a result, reduce a replacement frequency of the ionic liquid IL. Moreover, an opening 41b at a lower end of the storage tank 41 communicates with an inside of the viscosity pump 42. Inside the storage tank 41, the ionic liquid IL falls toward the opening 41b at the lower end due to gravity and is supplied to the viscosity pump 42, and air bubbles that may be included in the ionic liquid IL rise toward the liquid level LL due to buoyancy and deaerate at the liquid level LL. Hence, it is possible to prevent the air bubbles that may be included in the ionic liquid IL from entering into the viscosity pump 42. The deaeration of the ionic liquid IL can be performed while the viscosity pump 42 is being driven, and can also be performed while the viscosity pump 42 is stopped. The type of the ionic liquid IL is not particularly limited, and an ammonium type, an imidazolium type, or a pyridinium type may be utilized, for example.

The viscosity pump 42 is provided below the storage tank 41 in a vertical direction. In the present embodiment, the viscosity pump 42 includes a housing 421, a rotor 422, a stator 423, a bearing 424, and a rotational speed detector 425.

The housing 421 has a cylindrical shape having a center axis in the vertical direction. An upper end of the housing 421 is connected to the lower end of the storage tank 41, and an opening 421a at the upper end of the housing 421 and the opening 41b at the lower end of the storage tank 41 communicate with each other. Hence, the ionic liquid IL inside the storage tank 41 falls into the housing 421 via the opening 41b and the opening 421a due to gravity, and the inside of the housing 421 is filled with the ionic liquid IL. Accordingly, the ionic liquid can be supplied from the storage tank 41 into the housing 421 without using a negative pressure, a gas for pushing out the liquid, or the like. For this reason, when a predetermined amount of liquid is supplied from the inside of the housing 421 to the pipe 44, an amount of the ionic liquid identical to the predetermined amount is supplied from the inside of the storage tank 41 to the inside of the housing 421 due to gravity.

The housing 421 is provided coaxially with the storage tank 41, and is configured to have an inner diameter equal to an inner diameter of the storage tank 41 or smaller than the inner diameter of the storage tank 41. Thus, the air bubbles generated inside the housing 421 move upward in the vertical direction toward the inside of the processing chamber 1 without stagnating at a connector between the storage tank 41 and the housing 421. As a result, it is possible to efficiently remove the air bubbles inside the housing 421. In addition, in the case where the housing 421 is configured to have the inner diameter smaller than the inner diameter of the storage tank 41, it is preferable to provide a sloping surface that increases in diameter from the housing 421 toward the storage tank 41. The provision of the sloping surface can particularly reduce the stagnation of the air bubbles at the connector between the storage tank 41 and the housing 421.

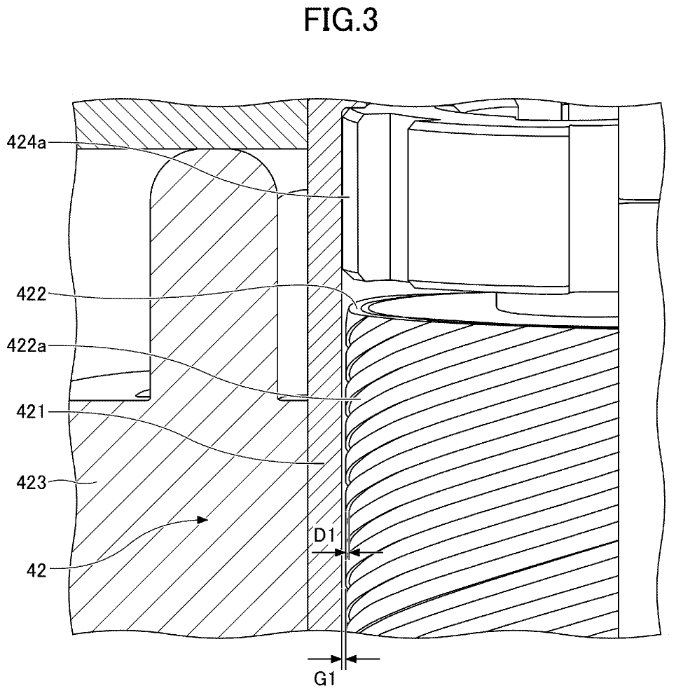

The rotor 422 is provided inside the housing 421, and is immersed in the ionic liquid IL. That is, the rotor 422 is provided below the liquid level LL of the ionic liquid IL in the vertical direction. The rotor 422 has a cylindrical shape having the center axis of the housing 421 as a rotation axis thereof. A length of the rotor 422 in an axial direction is two to three times a diameter of the rotor 422. The rotor 422 rotates inside the housing 421 to supply the ionic liquid inside the housing 421 to the pipe 44 using the viscosity of the ionic liquid. A gap G1 (FIG. 3) is provided between an outer peripheral surface of the rotor 422 and an inner peripheral surface of the housing 421. The gap G1 is 0.01 mm to 0.5 mm, for example, and may be 0.25 mm, for example. A spiral liquid feeding groove 422a (FIG. 3) having the rotation axis of the rotor 422 as a screw axis thereof is formed in the outer peripheral surface of the rotor 422. A depth D1 of the liquid feeding groove 422a is 0.01 mm to 1 mm, for example, and may be 0.22 mm, for example.

The stator 423 is provided outside the rotor 422, and generates a force for rotating the rotor 422. The stator 423 is a permanent magnet type stator, for example.

The bearing 424 includes an upper bearing block 424a and a lower bearing block 424b. The bearing 424 rotatably supports an upper portion of the rotor 422 by the upper bearing block 424a, and rotatably supports a lower portion of the rotor 422 by the lower bearing block 424b. The bearing 424 is preferably a fluid bearing. Hence, it is possible to prevent contamination, and to rotate the rotor 422 at a high speed. However, the bearing 424 may be a rolling bearing.

The rotational speed detector 425 includes a sensor rotor side 425a and a sensor stator side 425b, and is configured to detect a rotational speed of the rotor 422.

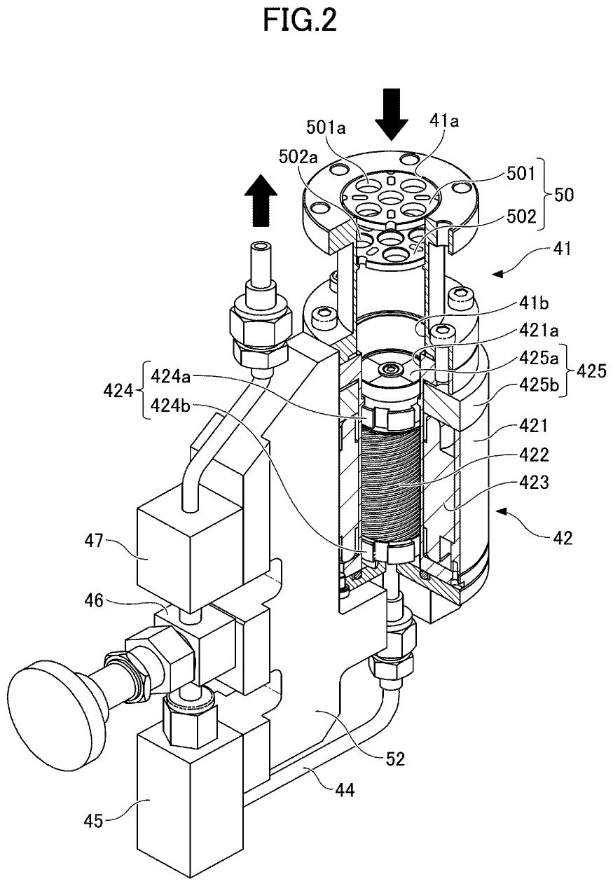

The diaphragm pump 43 is provided between the viscosity pump 42 and the pipe 44. In the present embodiment, the diaphragm pump 43 is connected to a lower portion of the viscosity pump 42. The diaphragm pump 43 supplies the ionic liquid IL supplied from the viscosity pump 42 to the pipe 44. The diaphragm pump 43 may be omitted, and FIG. 2 illustrates a case where the diaphragm pump 43 is not provided.

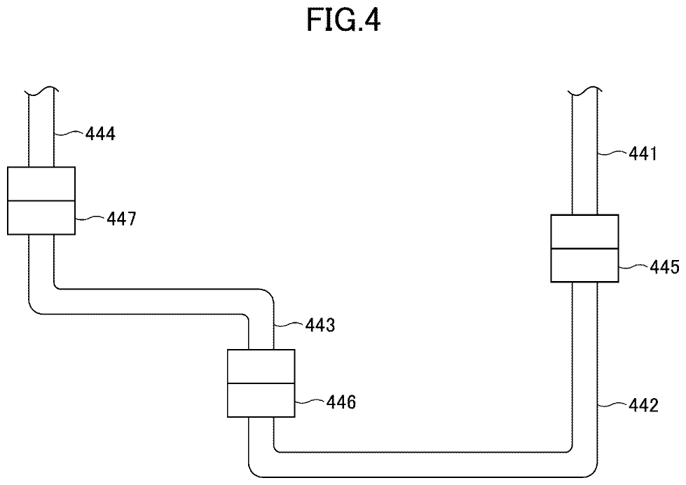

One end of the pipe 44 is airtightly connected to the diaphragm pump 43, and the other end of the pipe 44 is inserted into the processing chamber 1 through a bottom plate 11 of the processing chamber 1. Thus, the pipe 44 supplies the ionic liquid IL supplied from the diaphragm pump 43 into the processing chamber 1, and supplies the ionic liquid IL to the liquid utilization section 3. The pipe 44 is formed of a single pipe, for example. However, as illustrated in FIG. 4, the pipe 44 may be formed by a plurality of pipes, such as four pipes 441 through 444, for example. In the case where the pipe 44 is formed by the four pipes 441 through 444, it is preferable to provide joints 445 through 447 connecting the pipes 441 through 444 to one another, in the pipes extending in the vertical direction.

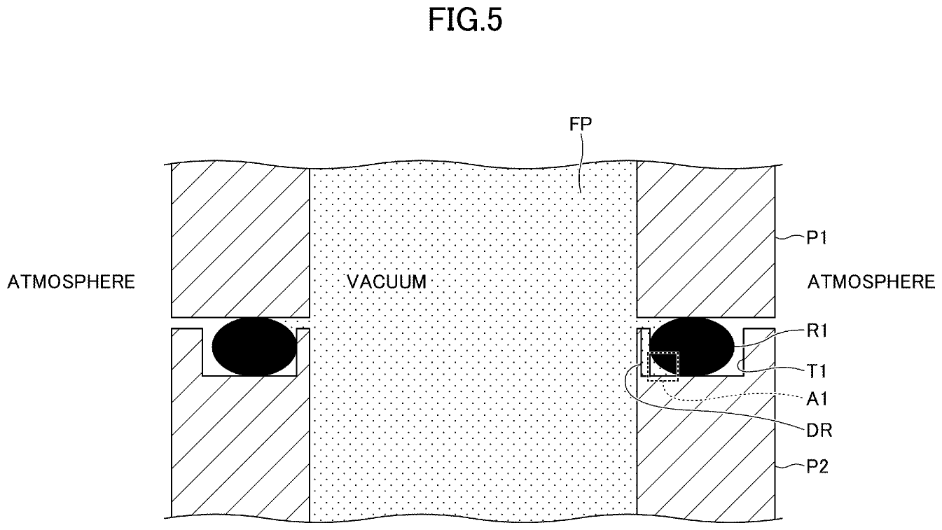

For example, as illustrated in FIG. 5, when pipes P1 and P2 extending in the vertical direction are connected to each other, the air bubbles generated inside a groove portion T1 to which an O-ring R1 is attached move to a flow path FP inside the pipes P1 and P2 while rising due to buoyancy. For this reason, it is possible to remove the air bubbles inside the groove portion T1. Further, as illustrated in FIG. 5, it is preferable to provide a drain DR, extending in the vertical direction from a bottom surface to an upper surface of the groove portion T1 and communicating to the flow path FP at the upper surface, in a portion of an inner peripheral surface of the groove portion T1 in a circumferential direction. Hence, the air bubbles in a region A1 surrounded by the inner peripheral surface of the groove portion T1, the bottom surface of the groove portion T1, and the O-ring R1 move to the flow path FP through the drain DP. For this reason, it is possible to efficiently remove the air bubbles inside the groove portion T1.

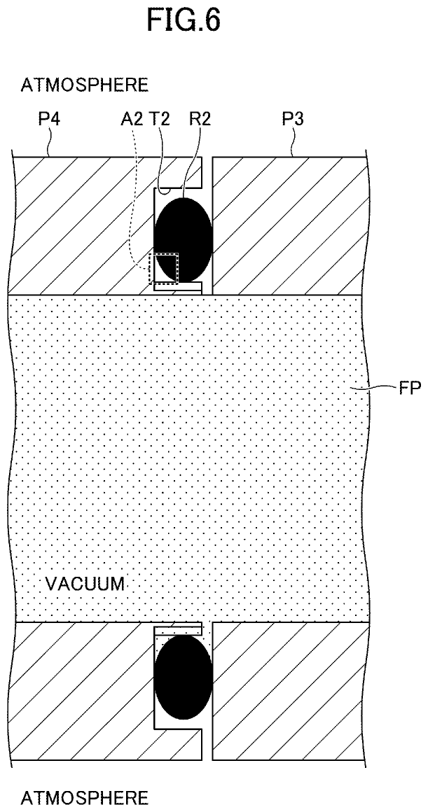

In contrast, as illustrated in FIG. 6, when pipes P3 and P4 extending in a horizontal direction are connected to each other, the air bubbles generated in a region A2 of a groove portion T2 to which an O-ring R2 is attached, located above a flow path FP inside the pipes P3 and P4 in the vertical direction, do not move to the flow path FP. For this reason, it is not possible to completely remove the air bubbles inside the groove portion T2.

The discharge pressure sensor 45, the flow rate controller 46, and the supply pressure sensor 47 are installed in the pipe 44 in this order from the end provided with the diaphragm pump 43.

The discharge pressure sensor 45 is installed in the pipe 44, and detects a discharge pressure of the ionic liquid IL discharged from the diaphragm pump 43. The discharge pressure sensor 45 transmits the detected discharge pressure to the flow rate controller 46.

The flow rate controller 46 is installed in the pipe 44. The flow rate controller 46 controls a flow rate of the ionic liquid IL flowing through the pipe 44, based on at least one of the discharge pressure detected by the discharge pressure sensor 45 and a supply pressure detected by the supply pressure sensor 47.

The supply pressure sensor 47 is installed in the pipe 44, and detects the supply pressure of the ionic liquid IL controlled of the flow rate by the flow rate controller 46 and supplied into the processing chamber 1. The supply pressure sensor 47 transmits the detected supply pressure to the flow rate controller 46.

The liquid recovery tray 48 is provided on the bottom plate 11 of the processing chamber 1, and has a funnel shape sloping toward the opening 41a of the storage tank 41. The liquid recovery tray 48 collects the ionic liquid IL utilized in the liquid utilization section 3 and recovers the ionic liquid IL into the opening 41a of the storage tank 41. By providing the liquid recovery tray 48, the ionic liquid IL becomes a thin liquid film when passing the sloping surface of the liquid recovery tray 48, thereby increasing a surface area of the ionic liquid IL and promoting deaeration of the ionic liquid IL.

The temperature controller 49 measures and controls a temperature of the ionic liquid IL inside the storage tank 41. In a case where the liquid utilization section 3 is a temperature control target and the temperature control target is to be cooled, for example, the temperature controller 49 performs a control so as to lower the temperature of the ionic liquid IL inside the storage tank 41. Further, in a case where the liquid utilization section 3 is the temperature control target and the temperature control target is to be heated, for example, the temperature controller 49 performs a control so as to raise the temperature of the ionic liquid IL inside the storage tank 41. Moreover, the temperature controller 49 may perform a control to lower the temperature of the ionic liquid IL inside the storage tank 41, so as to cool the viscosity pump 42.

The splash shield 50 is provided at the opening 41a of the storage tank 41. The splash shield 50 shields splash generated by breaking of the air bubbles at the liquid level LL when the deaeration of the ionic liquid IL inside the storage tank 41 occurs, so as to prevent the splash from entering the processing chamber 1 from the storage tank 41. In the present embodiment, the splash shield 50 includes an upper shielding plate 501 and a lower shielding plate 502. However, the splash shield 50 may be formed of a single shielding plate, or may be formed of three or more shielding plates.

The upper shielding plate 501 has a disk shape with an outer diameter that is approximately the same as a diameter of the opening 41a, and is provided so as to close the opening 41a. Thus, the splash from the storage tank 41 is blocked from entering into the processing chamber 1. A plurality of through holes 501a are formed in the upper shielding plate 501. Accordingly, the ionic liquid IL recovered by the liquid recovery tray 48 passes through the plurality of through holes 501a and falls downward in the vertical direction.

The lower shielding plate 502 is provided below the upper shielding plate 501 in the vertical direction, with a gap from the upper shielding plate 501. The lower shielding plate 502 has a disk shape with an outer diameter that is approximately the same as the diameter of the opening 41a, and is provided so as to close the opening 41a. Thus, the splash from the storage tank 41 is blocked from entering into the processing chamber 1. A plurality of through holes 502a are formed in the lower shielding plate 502. Accordingly, the ionic liquid IL that passed through the upper shielding plate 501 passes through the plurality of through holes 502a, falls downward in the vertical direction, and flows into the storage tank 41. The plurality of through holes 502a are preferably provided at positions different from positions of the plurality of through holes 501a in a plan view. Hence, even if the splash were to pass through the plurality of through holes 502a, the upper shielding plate 501 blocks the splash from scattering upward in the vertical direction, and thus, it is possible to particularly prevent the splash from entering inside the processing chamber 1 from inside the storage tank 41.

The measurement unit 51 monitors a state of the ionic liquid IL inside the storage tank 41. The measurement unit 51 monitors the degree of absorption of moisture and oxidizing gas in the vacuum, by measuring a specific resistance or colorimetry of the ionic liquid IL, for example. Thus, the degree of deterioration of the entire ionic liquid IL can easily be grasped, compared to a method of monitoring the state of the ionic liquid IL by sampling a portion of the ionic liquid IL.

The frame 52 holds each element of the liquid circulation system 4. For example, the frame 52 is attached to the viscosity pump 42, and holds the discharge pressure sensor 45, the flow rate controller 46, and the supply pressure sensor 47.

As described above, according to the liquid circulation system 4 of the embodiment, the viscosity pump 42 is provided below the storage tank 41 in the vertical direction. Hence, the ionic liquid IL is supplied from inside the storage tank 41 to the viscosity pump 42 due to gravity, and the air bubbles that may be included in the ionic liquid IL rise due to buoyancy and deaerate. For this reason, it is possible to prevent the air bubbles that may be included in the ionic liquid IL from entering into the viscosity pump 42. As a result, the ionic liquid IL can be continuously circulated in the vacuum while removing the air bubbles that may be included in the ionic liquid IL.

In addition, according to the liquid circulation system 4 of the embodiment, because the ionic liquid IL is circulated in a sealed state in the vacuum, the ionic liquid does not come into contact with a gas, and it is possible to maintain a quality of the ionic liquid. Hence, it is possible to reduce the replacement frequency of the ionic liquid introduced into the liquid circulation system 4.

Moreover, according to the liquid circulation system 4 of the embodiment, because a constant amount of the ionic liquid IL is circulated continuously without performing a suction and discharge process by opening and closing an on-off valve, it is possible to prevent a low-frequency pulsation from occurring in the discharge pressure.

Further, according to the liquid circulation system 4 of the embodiment, because all of the flow paths of the ionic liquid IL are in the vacuum state and the ionic liquid IL is circulated without utilizing a differential pressure, a seal structure (for example, a differential exhaust seal) for sealing the pressure difference is not required. This contributes to reducing the size of the liquid circulation system 4 and simplifying the configuration thereof.

In addition, according to the liquid circulation system 4 of the embodiment, because the ionic liquid IL is circulated without utilizing the differential pressure, the liquid circulation system 4 has a fail-safe configuration in which the circulation of the ionic liquid IL merely stops even in a case where power is lost due to a power failure or the like. In contrast, in the case where the ionic liquid IL is circulated by utilizing the differential pressure, there are concerns in that the inward flow or outward flow of the ionic liquid IL into or from the processing chamber 1 cannot be stopped when the power is lost.

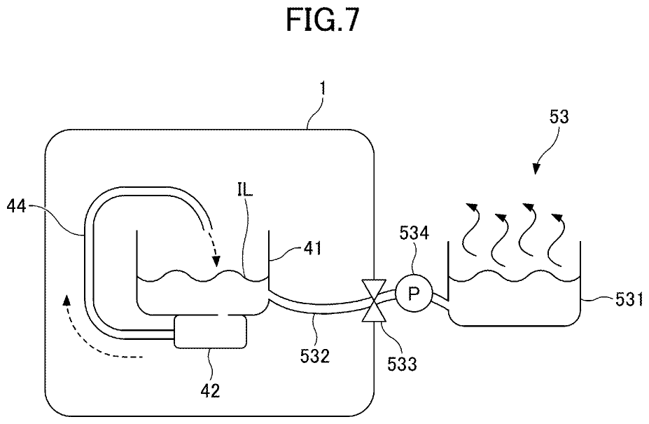

Moreover, the liquid circulation system 4 of the embodiment may include a liquid recycling mechanism 53, as illustrated in FIG. 7. The liquid recycling mechanism 53 includes a distillation device 531, a pipe 532, an on-off valve 533, and a diaphragm pump 534.

The distillation device 531 heats the ionic liquid IL to a temperature of 150° C. to 400° C., for example, to selectively evaporate and remove impurities (for example, moisture) included in the ionic liquid IL.

The pipe 532 connects the storage tank 41 and the distillation device 531. The on-off valve 533 and the diaphragm pump 534 are installed in the pipe 532 in this order from the end provided with the storage tank 41.

The on-off valve 533 is installed in the pipe 532, and opens and closes a flow path in the pipe 532. The on-off valve 533 is opened in a case where the ionic liquid IL is to be recycled, and is closed in other cases. The on-off valve 533 is a manual valve, for example, but may be an electromagnetic valve.

The diaphragm pump 534 is installed in the pipe 532. The diaphragm pump 534 is configured to supply the ionic liquid IL inside the storage tank 41 to the distillation device 531, and is also configured to return the ionic liquid IL inside the distillation device 531 back into the storage tank 41.

In the case where the ionic liquid IL is recycled by the liquid recycling mechanism 53, first, the pressure inside the processing chamber 1 is adjusted to a pressure that is the same as a pressure inside the distillation device 531 or to a pressure slightly higher than the pressure inside the distillation device 531. Next, the on-off valve 533 is opened, and the diaphragm pump 534 is driven, so as to supply the ionic liquid IL inside the storage tank 41 into the distillation device 531. Then, the ionic liquid IL is heated in the distillation device 531, so as to selectively evaporate and remove the impurities included in the ionic liquid IL. Next, the diaphragm pump 534 is driven to return the ionic liquid IL inside the distillation device 531 back into the storage tank 41. After the ionic liquid IL inside the distillation device 531 is returned into the storage tank 41, the diaphragm pump 534 is stopped and the on-off valve 533 is closed. The ionic liquid IL can be recycled by the process described above.

### [High-Temperature Gate Valve]

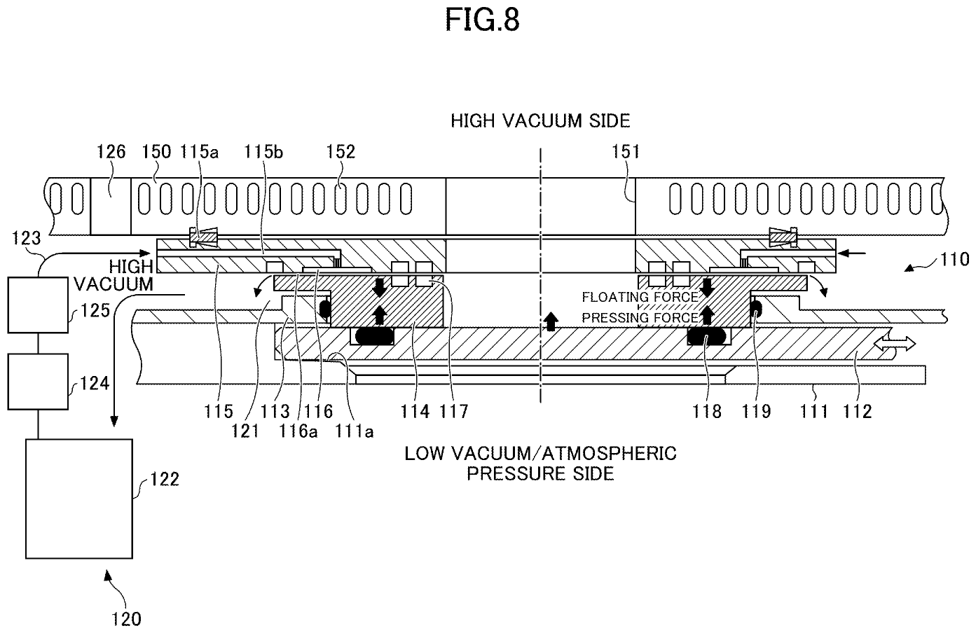

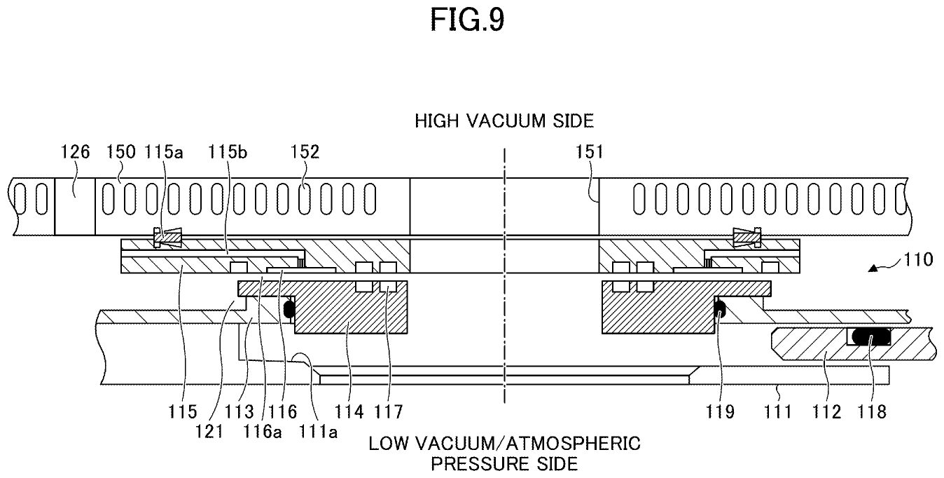

An example of a high-temperature gate valve to which the liquid circulation system of the embodiment can be applied will be described with reference to FIG. 8 and FIG. 9. FIG. 8 is a cross sectional view illustrating the high-temperature gate valve in a state in which a gate shutter is closed, and FIG. 9 is a cross sectional view illustrating the high-temperature gate valve in a state in which the gate shutter open.

The high-temperature gate valve opens and closes an opening 151 formed in a chamber wall 150 of a vacuum chamber. The inside of the vacuum chamber is maintained at an ultra-high vacuum or a high vacuum, for example. The chamber wall 150 has a heater 152 embedded therein, and is heated to a high temperature. The high-temperature gate valve includes a seal 110 and a liquid circulation system 120.

The seal 110 includes a housing 111, a gate shutter 112, a floating body holder 113, a floating body 114, a fluid bearing pad 115, a fluid bearing 116, a liquid recovery groove 117, and O-rings 118 and 119.

The housing 111 accommodates the gate shutter 112 in a state freely movable in the horizontal direction. A sloping surface 111a is provided in a portion of the housing 111 where a top end of the gate shutter 112 is accommodated. Thus, the gate shutter 112 is smoothly accommodated inside the housing 111.

The gate shutter 112 closes the opening 151 by moving to a position (closed position) overlapping the opening 151 in the plan view inside the housing 111 (FIG. 8). Hence, the inside of the vacuum chamber is airtightly sealed. On the other hand, the gate shutter 112 opens the opening 151 by moving to a position (open position) not overlapping the opening 151 in the plan view (FIG. 9). Accordingly, the inside and the outside of the vacuum chamber communicate with each other. The O-ring 118 is provided on an upper surface of the gate shutter 112 to airtightly seal a gap between the upper surface of the gate shutter and a lower surface of the floating body 114.

The floating body holder 113 is installed on the housing Ill. The floating body holder 113 holds the floating body 114 in a state in which the gate shutter 112 is moved to the open position. The O-ring 119 is provided on an inner peripheral surface of the floating body holder 113 to airtightly seal a gap between the inner peripheral surface of the floating body holder 113 and an outer peripheral surface of the floating body 114.

When the gate shutter 112 moves to the closed position, the floating body 114 is pressed upward in the vertical direction by the gate shutter 112 and separates from the floating body holder 113 (FIG. 8). On the other hand, when the gate shutter 112 moves to the open position, the floating body 114 moves downward in the vertical direction and lands on the floating body holder 113 because the pressing force of the gate shutter 112 is no longer applied (FIG. 9).

The fluid bearing pad 115 is connected to a lower surface of the chamber wall 150 via a metal gasket 115a. The fluid bearing pad 115 has a flow path 115b for supplying the ionic liquid IL supplied from a pipe 123 to the fluid bearing 116.

The fluid bearing 116 contactlessly supports the floating body 114, by supplying the ionic liquid IL pressurized by the liquid circulation system 120 to a bearing gap 116a formed by the fluid bearing pad 115 and the floating body 114.

The liquid recovery groove 117 is a flow path formed in the floating body 114 and the fluid bearing pad 115 for returning the ionic liquid IL supplied to the bearing gap 116a back into the liquid circulation system 120.

The liquid circulation system 120 includes a storage tank 121, a viscosity pump 122, a pipe 123, a temperature controller 124, a pressure adjustment mechanism 125, and a deaeration hole 126.

The storage tank 121 is a region surrounded by the floating body holder 113, the floating body 114, and the fluid bearing pad 115, and stores the ionic liquid IL. The ionic liquid IL flows into the storage tank 121 from the liquid recovery groove 117.

The viscosity pump 122 is provided below the storage tank 121 in the vertical direction. Hence, the ionic liquid IL inside the storage tank 121 falls into the viscosity pump 122 due to gravity, and the viscosity pump 122 is filled with the ionic liquid IL. The viscosity pump 122 may have the same configuration as the viscosity pump 42 described above. In addition, a diaphragm pump may be provided on a downstream side of the viscosity pump 122.

One end of the pipe 123 is airtightly connected to the viscosity pump 122, and the other end of the pipe 123 is connected to the flow path 115b. The pipe 123 supplies the ionic liquid IL supplied from the viscosity pump 122 into the flow path 115b. The pipe 123 may have the same configuration as the pipe 44 described above. The temperature controller 124 and the pressure adjustment mechanism 125 are installed in the pipe 123 in this order from the end provided with the viscosity pump 122.

The temperature controller 124 is installed in the pipe 123. The temperature controller 124 measures and adjusts the temperature of the ionic liquid IL flowing through the pipe 123. For example, the temperature controller 124 cools the ionic liquid IL flowing through the pipe 123, so as to supply the low-temperature ionic liquid IL to the fluid bearing 116. Thus, the floating body 114 can be cooled, and the temperature of the floating body 114 can be maintained in a temperature range in which the O-ring is usable.

The pressure adjustment mechanism 125 is installed in the pipe 123. The pressure adjustment mechanism 125 adjusts the pressure of the ionic liquid IL supplied to the pipe 123. The pressure adjustment mechanism 125 adjusts the pressure of the ionic liquid IL supplied to the fluid bearing 116, so that the position of the floating body 114 in the vertical direction can be accurately controlled. For example, by adjusting the pressure of the ionic liquid IL supplied to the fluid bearing 116, the floating body 114 can be separated from a high-temperature side (fluid bearing pad 115), and thus, it is possible to reduce the heat transmitted from the high-temperature side to the O-ring via the floating body 114. In addition, the amount of heat escaping from the high-temperature chamber wall 150 can be reduced.

The deaeration hole 126 is a through hole penetrating the chamber wall 150, and is located above the storage tank 121 in the vertical direction. The deaeration hole 126 communicates the inside of the storage tank 121 with the inside of the vacuum chamber. The air bubbles included in the ionic liquid IL inside the storage tank 121 move into the vacuum chamber via the deaeration hole 126, and are exhausted by an exhaust section (not illustrated) connected to the vacuum chamber.

As described above, according to the high-temperature gate valve, contact surfaces of the O-rings 118 and 119 are provided on the independent floating body 114 without mechanical fastening, and the O-rings 118 and 119 are prevented from being heated directly. When the gate shutter 112 moves to the closed position, the floating body 114 is pressed upward in the vertical direction by the gate shutter 112. In this state, the fluid bearing 116 on an upper surface of the floating body 114 supports the floating body 114 so as to push back against the pressing force. The floating body 114 stops at a position where the pressing force of the gate shutter 112 and a floating force of the fluid bearing 116 are balanced. Thus, the floating body 114 is contactlessly supported by the fluid bearing 116, and is prevented from mechanically contacting the high-temperature side by the bearing gap 116a. As a result, the opening 151 of the chamber wall 150 heated to a high temperature can be opened and closed by the gate shutter 112, using the O-rings 128 and 129.

Further, the high-temperature gate valve includes the temperature controller 124 that adjusts the temperature of the ionic liquid IL supplied to the bearing gap 116a. Thus, the floating body 114 is cooled by adjusting the ionic liquid IL supplied to the bearing gap 116a by the temperature controller 124, and the temperature of the floating body 114 can be maintained in the temperature range in which the O-rings 118 and 119 are usable.

### [High-Temperature Rotating Seal]

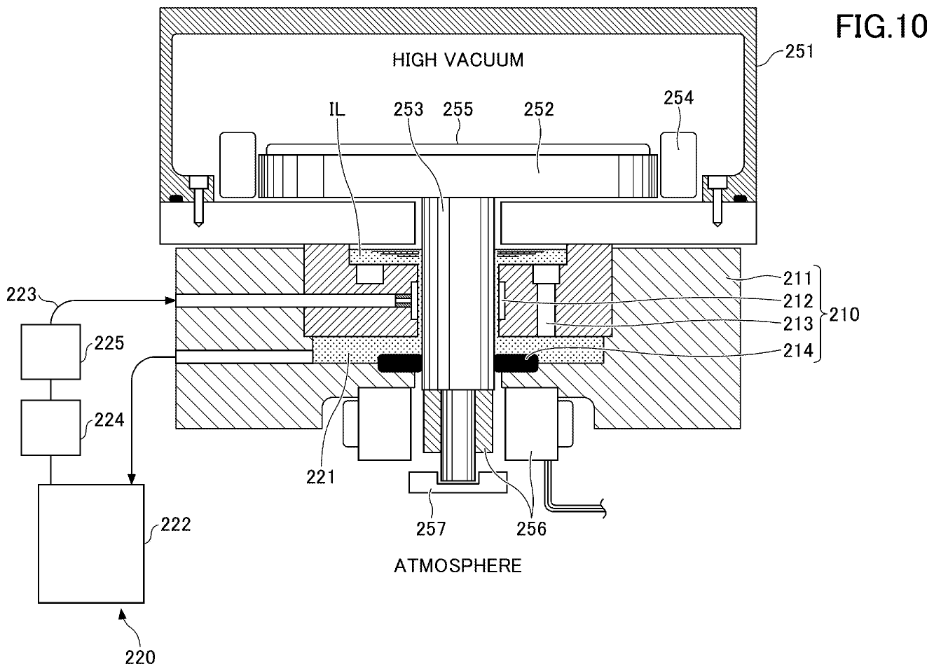

An example of a high-temperature rotating seal to which the liquid circulation system of the embodiment can be applied will be described with reference to FIG. 10.

The high-temperature rotating seal airtightly seals a rotating shaft 253 for rotating a rotary stage 252 provided inside the vacuum chamber 251. The inside of the vacuum chamber 251 is maintained at an ultra-high vacuum or a high vacuum, for example. A heating reactor 254 is provided inside the vacuum chamber 251, and the rotary stage 252 is adjusted to a high temperature by the heating reactor 254. A substrate 255, that is a processing target to be processed, is placed on the rotary stage 252. The rotating shaft 253 is connected to a lower portion of the rotary stage 252, and is rotated by a motor 256 with the vertical direction as a rotation axis. The rotating shaft 253 is supported by a thrust bearing 257. The high-temperature rotating seal includes a high-temperature seal 210 and a liquid circulation system 220.

The high-temperature seal 210 includes a bearing housing 211, a fluid bearing 212, a liquid circulation passage 213, and a shaft seal 214.

The bearing housing 211 has a hollow shape, and the rotating shaft 253 is inserted into the hollow portion. The bearing housing 211 forms the liquid circulation passage 213.

The fluid bearing 212 contactlessly supports the rotating shaft 253 by supplying the ionic liquid IL pressurized by the liquid circulation system 220 to a bearing gap formed by the rotating shaft 253 and the bearing housing 211.

The liquid circulation passage 213 is a flow path that is formed by the bearing housing 211 for returning the ionic liquid IL supplied to the bearing gap back to the liquid circulation system 220.

The shaft seal 214 is provided inside a storage tank 221 which will be described later, and is immersed in the ionic liquid IL. The shaft seal 214 rotatably and airtightly seals the rotating shaft 253 with respect to the bearing housing 211. The shaft seal 214 is an O-ring, a magnetic fluid seal, or the like.

The liquid circulation system 220 includes the storage tank 221, a viscosity pump 222, a pipe 223, a temperature controller 224, and a pressure adjustment mechanism 225.

The storage tank 221 is formed inside the bearing housing 211, and stores the ionic liquid IL. The ionic liquid IL flows into the storage tank 221 from the liquid circulation passage 213.

The viscosity pump 222 is provided below the storage tank 221 in the vertical direction. Hence, the ionic liquid IL inside the storage tank 221 falls into the viscosity pump 222 due to gravity, and the viscosity pump 222 is filled with the ionic liquid IL. The viscosity pump 222 may have the same configuration as the viscosity pump 42 described above. In addition, a diaphragm pump may be provided on a downstream side of the viscosity pump 222.

One end of the pipe 223 is airtightly connected to the viscosity pump 222, and the other end of the pipe 223 is inserted into the fluid bearing 212 by penetrating the bearing housing 211 in the horizontal direction. The pipe 223 supplies the ionic liquid IL supplied from the viscosity pump 222 into the fluid bearing 212. The pipe 223 may have the same configuration as the pipe 44 described above. The temperature controller 224 and the pressure adjustment mechanism 225 are installed in the pipe 223 in this order from the end provided with the viscosity pump 222.

The temperature controller 224 is installed in the pipe 223. The temperature controller 224 measures and adjusts the temperature of the ionic liquid IL flowing through the pipe 223. For example, the temperature controller 224 cools the ionic liquid IL flowing through the pipe 223, so as to supply the low-temperature ionic liquid IL to the fluid bearing 212. Hence, it is possible to cool the rotating shaft 253, and to cool the shaft seal 214 immersed inside the storage tank 221. For this reason, the temperature of the portion in contact with the shaft seal 214 becomes the usable temperature of the O-ring, and thus, the O-ring can be used as the shaft seal 214.

The pressure adjustment mechanism 225 is installed in the pipe 223. The pressure adjustment mechanism 225 adjusts the pressure of the ionic liquid IL supplied to the pipe 223.

As described above, according to the high-temperature rotating seal, the rotating shaft 253 is cooled to the temperature at which the shaft seal 214 is usable by immersing the shaft seal 214 into the ionic liquid IL. Hence, it becomes unnecessary to provide a long shaft as the rotating shaft 253, and the size of the rotating shaft 253 can be reduced.

Further, according to the high-temperature rotating seal, the temperature controller 224 measures and adjusts the temperature of the circulating ionic liquid IL. Thus, it is possible to omit a temperature measurement element (for example, a thermocouple) provided on the chamber wall of the vacuum chamber 251 or on the rotating shaft 253, and reduce the number of temperature measurement elements required.

The embodiments disclosed herein are to be considered in all respects as illustrative and not restrictive. The above described embodiments may be omitted, replaced, and modified in various forms without departing from the scope and spirit of the appended claims.

This application is based upon and claims priority to Japanese Patent Application No. 2021-180011, filed on Nov. 4, 2021, the entire contents of which are incorporated herein by reference.

### DESCRIPTION OF THE REFERENCE NUMERALS

1: Processing chamber
4: Liquid circulation system
41: Storage tank
41a: Opening
42: Viscosity pump
44: Pipe
IL: Ionic liquid

1. A liquid circulation system for recovering an ionic liquid supplied into a vacuum chamber and returning the recovered ionic liquid back again into the vacuum chamber, the liquid circulation system comprising:
a storage tank, having an opening communicating with an inside of the vacuum chamber, and configured to store the ionic liquid recovered from the inside of the vacuum chamber through the opening;
a viscosity pump provided below the storage tank in a vertical direction; and
a pipe configured to supply the ionic liquid inside the storage tank into the vacuum chamber.

2. The liquid circulation system as claimed in claim 1, wherein the viscosity pump is connected to a lower end of the storage tank.

3. The liquid circulation system as claimed in claim 1, wherein the viscosity pump includes a cylindrical housing, and a rotor configured to rotate inside the housing with a center axis of the housing as a rotation axis thereof.

4. The liquid circulation system as claimed in claim 3, wherein the rotor is provided below a liquid level of the ionic liquid in the vertical direction.

5. The liquid circulation system as claimed in claim 3, wherein a spiral groove is formed in an outer peripheral surface of the rotor.

6. The liquid circulation system as claimed in claim 3, wherein a gap is provided between an outer peripheral surface of the rotor and an inner peripheral surface of the housing.

7. The liquid circulation system as claimed in claim 3, wherein the storage tank has a cylindrical shape with an inner diameter greater than or equal to an inner diameter of the housing.

8. The liquid circulation system as claimed in claim 1, further comprising:
a diaphragm pump provided between the viscosity pump and the pipe.

9. The liquid circulation system as claimed in claim 1, further comprising:
a flow rate controller configured to control a flow rate of the ionic liquid flowing through the pipe.

10. The liquid circulation system as claimed in claim 9, further comprising:
a sensor configured to detect a pressure inside the pipe,
wherein the flow rate controller controls the flow rate based on the pressure detected by the sensor.

11. The liquid circulation system as claimed in claim 1, further comprising:
a splash shield, provided at the opening of the storage tank, and configured to shield splash from the inside of the storage tank from entering into the vacuum chamber.

12. The liquid circulation system as claimed in claim 1, further comprising:
a temperature controller configured to control a temperature of the ionic liquid inside the storage tank.

13. The liquid circulation system as claimed in claim 1, wherein the inside of the vacuum chamber is maintained at an ultrahigh vacuum of 10⁻⁵ Pa to 10⁻⁸ Pa.

14. A substrate processing apparatus comprising:
a vacuum chamber configured to process a substrate; and
a liquid circulation system configured to recover an ionic liquid supplied into the vacuum chamber and return the ionic liquid back again into the vacuum chamber,
wherein the liquid circulation system includes:
a storage tank, having a first opening communicating with an inside of the vacuum chamber, and configured to store the ionic liquid recovered from the inside of the vacuum chamber through the first opening;
a viscosity pump provided below the storage tank in a vertical direction; and
a pipe configured to supply the ionic liquid inside the storage tank into the vacuum chamber.

15. The substrate processing apparatus as claimed in claim 14, further comprising:
a gate valve configured to open and close a second opening formed in a chamber wall of the vacuum chamber,
wherein the gate valve includes:
a gate shutter configured to move between a position to close the second opening and a position to open the second opening;
a floating body pressed upward in the vertical direction by the gate shutter; and
a fluid bearing, supplied with the ionic liquid from the liquid circulation system, and configured to support the floating body by pressing the floating body downward in the vertical direction.

16. The substrate processing apparatus as claimed in claim 14, further comprising:
a rotary stage provided inside the vacuum chamber;
a rotating shaft, connected to a lower portion of the rotary stage, and configured to rotate the rotary stage;
a bearing housing having a hollow shape, with the rotating shaft inserted into a hollow portion of the bearing housing; and
a fluid bearing, supplied with the ionic liquid from the liquid circulation system, and configured to support the rotating shaft with respect to the bearing housing.

17. A liquid circulation method for recovering an ionic liquid supplied into a vacuum chamber and returning the recovered ionic liquid back again into the vacuum chamber, the liquid circulation method comprising:
recovering the ionic liquid from inside the vacuum chamber through an opening communicating with the vacuum chamber, and storing the ionic liquid recovered from the inside of the vacuum chamber into a storage tank; and
supplying the ionic liquid into the vacuum chamber via a pipe by a viscosity pump provided below the storage tank in the vertical direction.
